(19) United States
(12) Patent Application Publication
(10) Pub. No.: US 2024/0160804 A1
(43) Pub. Date: May 16, 2024

(54) SURROGATE MODEL FOR VEHICLE SIMULATION

(71) Applicant: GM Cruise Holdings LLC, San Francisco, CA (US)

(72) Inventors: Matthew Kowalski, Yorktown, VA (US); Luke Murchison, Belmont, CA (US); Huseyin Erdim, Kirkland, WA (US); Lynn Marie Sarcione, Austin, TX (US)

(73) Assignee: GM Cruise Holdings LLC, San Francisco, CA (US)

(21) Appl. No.: 18/055,756

(22) Filed: Nov. 15, 2022

(51) Int. Cl. G06F 30/20; B60W 50/00

(52) U.S. Cl. CPC G06F 30/20; B60W 50/0097; B60W 60/001

(57) ABSTRACT

Systems and methods for generation and application of a road data response prediction model for evaluation of vehicle simulation are provided. A computer-implemented system, including one or more non-transitory computer-readable media storing instructions, when executed by one or more processing units, cause the one or more processing units to perform operations including receiving road data collected from a reference driving scene; extracting, from the road data, features of the reference driving scene; obtaining, from the road data, response data associated with a vehicle in the reference driving scene and responsive to the extracted features; calculating a statistical measure of the response data; and generating a road data response prediction model to map the extracted features of the road data to the statistical measure of the response data.

### BACKGROUND

### 1. Technical Field

The present disclosure generally relates to autonomous vehicles and, more specifically, to generation and application of a surrogate model for evaluation of vehicle simulation.

### 2. Introduction

Autonomous vehicles, also known as self-driving cars, driverless vehicles, and robotic vehicles, may be vehicles that use multiple sensors to sense the environment and move without human input. Automation technology in the autonomous vehicles may enable the vehicles to drive on roadways and to accurately and quickly perceive the vehicle's environment, including obstacles, signs, and traffic lights. Autonomous technology may utilize map data that can include geographical information and semantic objects (such as parking spots, lane boundaries, intersections, crosswalks, stop signs, traffic lights) for facilitating the vehicles in making driving decisions. The vehicles can be used to pick up passengers and drive the passengers to selected destinations. The vehicles can also be used to pick up packages and/or other goods and deliver the packages and/or goods to selected destinations.

### BRIEF DESCRIPTION OF THE DRAWINGS

The various advantages and features of the present technology will become apparent by reference to specific implementations illustrated in the appended drawings. A person of ordinary skill in the art will understand that these drawings show only some examples of the present technology and would not limit the scope of the present technology to these examples. Furthermore, the skilled artisan will appreciate the principles of the present technology as described and explained with additional specificity and detail through the use of the accompanying drawings in which:

FIG. 1 illustrates a road data response prediction model generation scheme, according to some examples of the present disclosure;

FIG. 2 illustrates a road data response prediction model generation scheme, according to some examples of the present disclosure;

FIG. 3 illustrates a road data response prediction model application scheme, according to some examples of the present disclosure;

FIG. 4 illustrates a road data response prediction model application scheme, according to some examples of the present disclosure;

FIG. 5 is a graph of observed sensor response statistics from a real-world driving scene versus sensor response statistics from a simulation, according to some examples of the present disclosure;

FIG. 6 illustrates a road data response prediction model application scheme, according to some examples of the present disclosure;

FIG. 7 illustrates a road data response prediction model application scheme, according to some examples of the present disclosure;

FIG. 8 illustrates a road data response prediction model generation process, according to some examples of the present disclosure;

FIG. 9 illustrates a road data response prediction model application process, according to some examples of the present disclosure;

FIG. 10 illustrates an example system environment that may be used to facilitate AV dispatch and operations, according to some aspects of the disclosed technology; and

FIG. 11 illustrates an example processor-based system with which some aspects of the subject technology may be implemented.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form to avoid obscuring the concepts of the subject technology.

Autonomous vehicles (AVs) can provide many benefits. For instance, AVs may have the potential to transform urban living by offering opportunities for efficient, accessible and affordable transportation. An AV may be equipped with various sensors to sense an environment surrounding the AV and collect information (e.g., sensor data) to assist the AV in making driving decisions. To that end, the collected information or sensor data may be processed and analyzed to determine a perception of the AV's surroundings, extract information related to navigation, and predict future motions of the AV and/or other traveling agents in the AV's vicinity. The predictions may be used to plan a path for the AV (e.g., from a starting position to a destination). As part of planning, the AV may access map information and localize itself based on location information (e.g., from location sensors) and the map information. Subsequently, instructions can be sent to a controller to control the AV (e.g., for steering, accelerating, decelerating, braking, etc.) according to the planned path.

The operations of perception, prediction, planning, and control of an AV may be implemented using a combination of hardware and software components. For instance, an AV stack or AV compute process performing the perception, prediction, planning, and control may be implemented using one or more of software code and/or firmware code. However, in some embodiments, the software code and firmware code may be supplemented with hardware logic structures to implement the AV stack and/or AV compute process. The AV stack or AV compute process (the software and/or firmware code) may be executed on processor(s) (e.g., general purpose processors, central processing units (CPUs), graphical processing units (GPUs), digital signal processors (DSPs), application specific integrated circuits (ASICs), etc.) and/or any other hardware processing components on the AV. Additionally, the AV stack or AV compute process may communicate with various hardware components (e.g., onboard sensors and control systems of the AV) and/or with an AV infrastructure over a network.

Training and testing AVs in the physical world can be challenging. For instance, to provide good testing coverage, an AV may be trained and tested to respond to various driving scenarios (e.g., millions of physical road test scenarios) before it can be deployed in an unattended, real-life roadway system. As such, it may be costly and time-consuming to train and test AVs on physical roads. Further, there may be test cases that are difficult to create or too dangerous to cover in the physical world. Accordingly, it may be desirable to train and validate AVs in a simulation environment.

A simulator may simulate (or mimic) real-world conditions (e.g., roads, lanes, buildings, obstacles, other traffic participants, trees, lighting conditions, weather conditions, etc.) so that the AV stack and/or AV compute process of an AV may be tested in a virtual environment that is close to a real physical world. Testing AVs in a simulator can be more efficient and allow for creation of specific traffic scenarios and/or specific road objects. To that end, the AV compute process implementing the perception, prediction, planning, and control algorithms can be developed, validated, and fine-tuned in a simulation environment. More specifically, sensors on an AV used for perception of a driving environment can be modeled in an AV simulator, the AV compute process may be executed in the AV simulator, and the AV simulator may compute metrics related to AV driving decisions, AV response time, etc. to determine the performance of an AV to be deployed with the AV compute process.

To be able to evaluate the performance of an AV compute process based on a simulation and to obtain the expected result when the AV compute process is deployed in a vehicle for real-world driving, the fidelity of the simulation in replicating a real-world driving scenario and operations of vehicle sensors and/or any other vehicle components can be important.

Disclosed herein are techniques for generating a surrogate model for use as a proxy for road data and applying the surrogate model to evaluate simulation performance relative to road data (e.g., data associated with an AV driving in a real-world driving scene). The surrogate model may be a statistical model that models input-to-output behavior related to AV driving. For instance, the input to the model may be features (salient features) associated with a driving scene, and the output of the model may be statistical measure(s) of a response associated with the AV in response to the features in the driving scene. In certain aspects, the features may be associated with object(s) in the driving scene, and the response may be associated with sensor signals returned from the object(s). The present disclosure may generally refer to the surrogate model as a road data response prediction model.

According to an aspect of the present disclosure, a computer-implemented system may receive road data collected from a reference driving scene. The computer-implemented system may extract, from the road data, features of the reference driving scene. The computer-implemented system may obtain, from the road data, response data associated with a vehicle in the reference driving scene and responsive to the extracted features. The computer-implemented system may calculate a statistical measure of the response data. The computer-implemented system may generate a road data response prediction model to map the features of the road data to the statistical measure of the response data. Stated differently, the road data response prediction model is generated to predict a statistical measure of a response given a set of input road features. In some aspects, the road data response prediction model may be a statistical model (e.g., a generalized linear model (GLM)).

In some aspects, the reference driving scene can be a real-world driving scene. In other aspects, the reference driving scene may be a simulated driving scene or synthetic driving scene (from a high-fidelity simulation). As used herein, a fidelity of a simulation may refer to the accuracy of the simulation in replicating certain aspect(s) of a real-world driving scene. A high-fidelity simulation may refer to a simulation that can accurately replicate certain aspects(s) of a real-world driving scene.

In some aspects, the response data may include sensing information associated with the reference driving scene. For instance, the sensing information may be based on sensing signals returned from object(s) in the reference driving scene. Further, the road data response prediction model may be generated to map the extracted features to the statistical measure of the sensing information.

In some aspects, the response data may include a light detection and ranging (LIDAR) responsive to an object in the reference driving scene. In this regard, a LIDAR sensor (at the vehicle) may send light signals and the light signals reflected by the object may be received by the LIDAR sensor in which a point cloud representative of the object may be generated. The statistical measure for the response data may be a quantity (e.g., a total number) of LIDAR data points in the point cloud generated from the LIDAR returns (the reflected light signals). In some instances, the object may include at least one of a vehicle, a pedestrian, or a cyclist in the reference driving scene. In general, the object can be any object (stationary or dynamic) in the reference driving scene.

In some aspects, the features extracted from the road data can include an indication of a dimension of the object. For instance, a three-dimensional (3D) bounding box may be used to describe a dimension of the object in a 3D space, and thus the features can include a width, a length, height, and/or an area of the 3D bounding box. Additionally or alternatively, the features extracted from the road data can include an indication of a distance (e.g., a lateral distance and/or a longitudinal distance) from the object to the vehicle in the reference driving scene. Additionally or alternatively, the features extracted from the road data can include an indication of an angle (e.g., an object angle) at which the object is located with respect to (a reference coordinate system of) the vehicle in the reference driving scene. Additionally or alternatively, the features extracted from the road data can include an indication of an angle (e.g., an object bearing angle) between a path (or trajectory) of the object and a path (or trajectory) of the vehicle in the reference driving scene.

In some aspects, the road data response prediction model can model at least one of a linear term associated with a single feature of the extracted features, a linear term associated with a product of at least two features of the extracted features, or a nonlinear term associated with an individual feature of the extracted features.

According to a further aspect of the present disclosure, a computer-implemented system may determine a plurality of feature values associated with a driving scene. The computer-implemented system may further query the road data response prediction model based on the plurality of feature values to obtain a predicted the statistical measure of a response (e.g., a sensor response) for the driving scene with respect to a vehicle in the driving scene. In some aspects, the response may be associated with LIDAR sensing, the predicted statistical measure may include a predicted total number of LIDAR data points responsive to the driving scene. For instance, the road data response prediction model may be used as a proxy for road data. In other words, the road data response prediction model may predict a statistical measure of a sensor response for any object with features within ranges that are modeled by the road data response prediction model. As such, the road data response prediction model can provide an expected statistical measure of a sensor response for an object that has not been captured by a real-world sensor.

In some aspects, the road data response prediction model can be used to evaluate the fidelity of a simulation relative to a reference driving scene. For instance, the computer-implemented system may further execute a sensor test in a simulation that simulates the driving scene, where the determining the plurality of feature values may be based the simulation (e.g., by extracting features from the simulation). The computer-implemented system may further determine a fidelity of the simulation by comparing the predicted sensor response statistical measure obtained from the query to a reference statistical measure (e.g., a statistical measure of a reference sensor response). In some instances, the reference sensor response can be captured by a real-world sensor in a real-world driving scene and the reference statistical measure can be calculated from the reference sensor response. Alternatively, the reference sensor response may be obtained from a high-fidelity simulation.

In some aspects, the road data response prediction model can be used in a closed loop to improve the fidelity of the simulation. For instance, the computer-implemented system may iteratively adjust a parameter of the simulation based on a comparison between the reference statistical measure of the reference sensor response and a predicted sensor response statistical measure predicted by the road data response prediction model in a previous iteration.

The systems, schemes, and mechanisms described herein can advantageously provide a road data response prediction model that can be used as a proxy for road data. Additionally, the road data response prediction model can be used to evaluate simulation performance relative to road data (e.g., in comparison to AV performance in a real-world driving scene). Further, the road data response prediction model can be used for performing regressions in simulation codebase updates, for example, to evaluate different versions of simulation code. For instance, utilizing the road data response prediction model to map features to a statistical measure of a response can advantageously provide statistical information about a simulation performance quickly without having to run an entire simulation test suite, and thus may save time and cost. Still further, using the road data response prediction model in a closed loop can allow for continuous improvements to be made to the simulation.

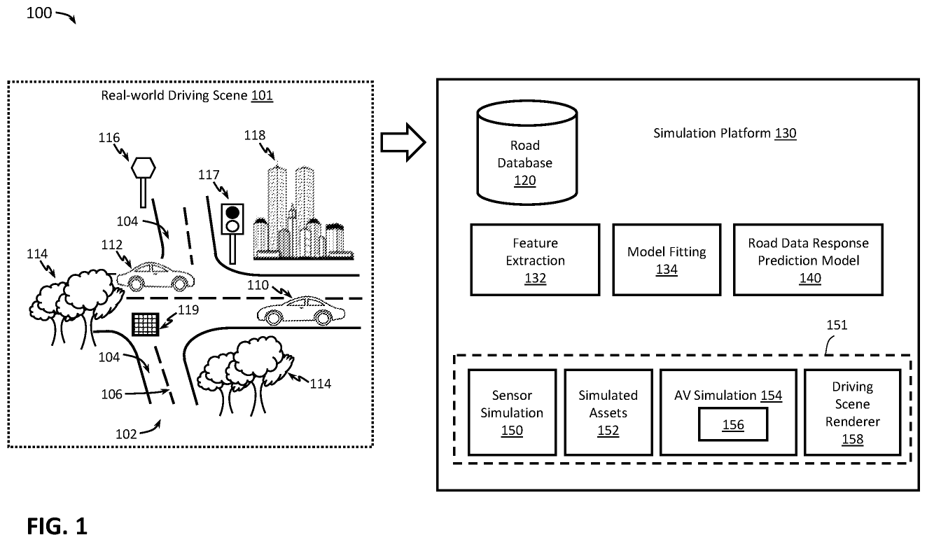

FIG. 1 illustrates a road data response prediction model generation scheme 100, according to some examples of the present disclosure. As shown in FIG. 1, a real-world driving scene 101 may include an AV 110 driving on a roadway system 102. The roadway system 102 may include roads and lanes 104 and road markings 106. Other vehicles, such as a vehicle 112, may also be driving on the roadway system 102. As further shown in FIG. 1, the real-world driving scene 101 may include trees 114, a road sign 116, a traffic light 117, buildings 118, and an object 119 (e.g., an obstacle, a road barrier, a traffic cone, etc.) located around the roadway system 102. In general, the real-world driving scene 101 may include various roadside objects (e.g., moving objects and/or stationary objects) at various locations. In some instances, the real-world driving scene 101 may be part of an operational design domain (ODD). An ODD is a specific domain in which an autonomous driving system is designed to operate.

The AV 110 may be a fully autonomous vehicle or a semi-autonomous vehicle. A fully autonomous vehicle may make driving decisions and drive the vehicle without human inputs. A semi-autonomous vehicle may make at least some driving decisions without human inputs. In some examples, the AV 110 may be a vehicle that switches between a semi-autonomous state and a fully autonomous state and thus, the AV 110 may have attributes of both a semi-autonomous vehicle and a fully autonomous vehicle depending on the state of the vehicle.

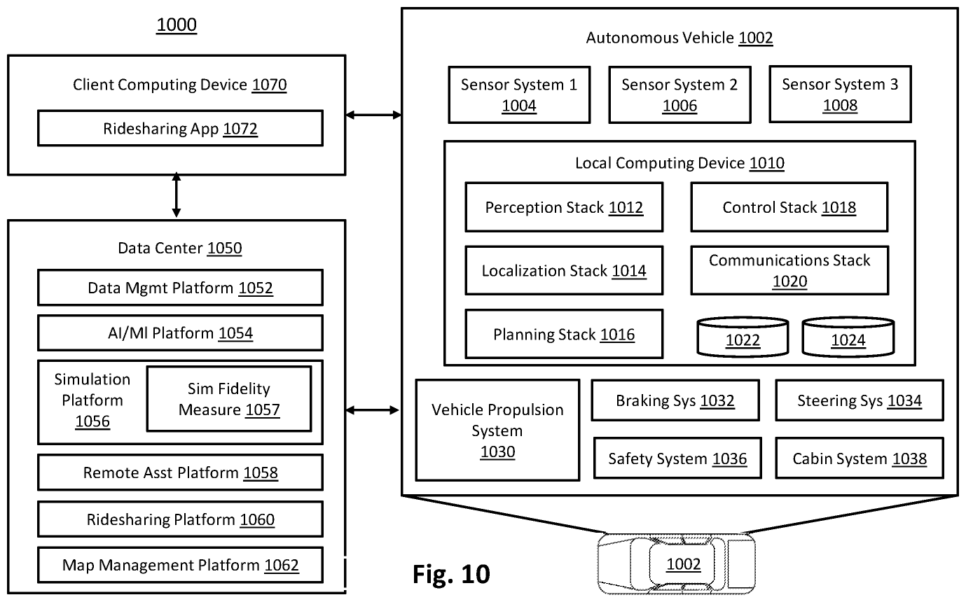

As will be discussed more fully below with reference to FIG. 10, the AV 110 may include various sensors and an onboard computer or local computing device. The sensors may include a wide variety of sensors, which may broadly categorize into a computer vision (“CV”) system, localization sensors, and driving sensors. As an example, the AV 110's sensors may include one or more cameras. The one or more cameras may capture images of the surrounding environment of the AV 110. In some instances, the sensor may include multiple cameras to capture different views, e.g., a front-facing camera, a back-facing camera, and side-facing cameras. In some instances, one or more cameras may be implemented using a high-resolution imager with a fixed mounting and field of view. One or more cameras may have adjustable field of views and/or adjustable zooms. In some embodiments, the cameras may capture images continually or at some intervals during operation of the AV 110. The cameras may transmit the captured images to the onboard computer of the AV 110 for further processing, for example, to assist the AV 110 in determining certain action(s) to be carried out by the AV 110.

Additionally or alternatively, the AV 110's sensors may include one or more light detection and ranging (LIDAR) sensors. The one or more LIDAR sensors may measure distances to objects in the vicinity of the AV 110 using reflected laser light. The one or more LIDAR sensors may include a scanning LIDAR that provides a point cloud of the region scanned. The one or more LIDAR sensors may have a fixed field of view or a dynamically configurable field of view. The one or more LIDAR sensors may produce a point cloud (e.g., a collection of data points in a 3D space) that describes the shape, contour, and/or various characteristics of one or more object in the surrounding of the AV 110 and a distance of the object away from the AV 110. For instance, the point cloud may include data points representing at least some of the trees 114, the road sign 116, the traffic light 117, the buildings 118, and the object 119 located around the roadway system 102. The one or more LIDAR sensors may transmit the captured point cloud to the onboard computer of the AV 110 for further processing, for example, to assist the AV 110 in determining certain action(s) to be carried out by the AV 110.

Additionally or alternatively, the AV 110's sensors may include one or more radio detection and ranging (RADAR) sensors. RADAR sensors may operate in substantially the same way as LIDAR sensors, but instead of the light waves used in LIDAR sensors, RADAR sensors use radio waves (e.g., at frequencies of 24, 74, 77, and 79 gigahertz (GHz)). The time taken by the radio waves to return from the objects or obstacles to the AV 110 is used for calculating the distance, angle, and velocity of the obstacle in the surroundings of the AV 110.

Additionally or alternatively, the AV 110's sensors may include one or more location sensors. The one or more location sensors may collect data that is used to determine a current location of the AV 110. The location sensors may include a global positioning system (GPS) sensor and one or more inertial measurement units (IMUs). The one or more location sensors may further include a processing unit (e.g., a component of the onboard computer, or a separate processing unit) that receives signals (e.g., GPS data and IMU data) to determine the current location of the AV 110. The location determined by the one or more location sensors can be used for route and maneuver planning. The location may also be used to determine when to capture images of a certain object. The location sensor may transmit the determined location information to the onboard computer of the AV 110 for further processing, for example, to assist the AV 110 in determining certain action(s) to be carried out by the AV 110.

In general, the AV 110's sensors may include any suitable sensors including but not limited to, photodetectors, one or more cameras, RADAR sensors, sound navigation and ranging (SONAR) sensors, LIDAR sensors, GPS, wheel speed sensors, weather sensors, IMUs, accelerometers, microphones, strain gauges, pressure monitors, barometers, thermometers, altimeters, etc. Further, the sensors may be located in various positions in and around the AV 110.

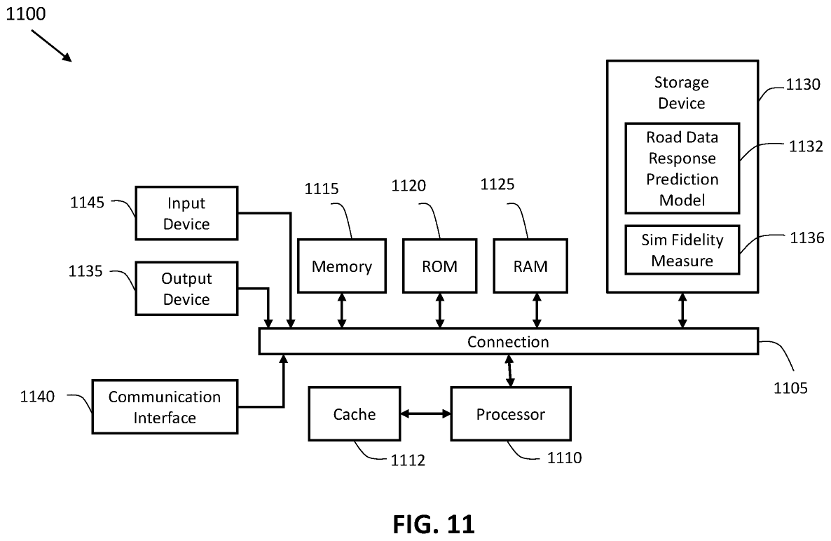

The AV 110's onboard computer may include one or more processors, memory, communication interface, for example, similar to the system 1100 of FIG. 11. In an example, the onboard computer may receive data collected from the AV 110's sensors and may store the collected sensor data at a memory of the onboard computer. As an example, the onboard computer may implement an AV compute process. An AV compute process (e.g., an AV software stack) may be executed on the AV 110's onboard computer to determine a driving decision based on the collected sensor data. To that end, the AV compute process may perform the tasks of perception, prediction, planning, and control.

For perception, the AV compute process may perform analyze the collected sensor data (e.g., camera images, point clouds, location information, etc.) and output an understanding or a perception of the environment surrounding the AV 110. In particular, the AV compute process may extract information related to navigation and making driving decisions. For instance, the AV compute process may detect objects including, but not limited to, cars, pedestrians, trees, bicycles, and objects traveling on or near the roadway systems 102 on which the AV 110 is traveling, and indications surrounding the AV 110 (such as construction signs, traffic cones, traffic lights, stop indicators, and other street signs). In the illustrated example of FIG. 1, the AV compute process may detect one or more of the vehicle 112, the trees 114, the road sign 116, the traffic light 117, the buildings 118, and/or the objects 119 in the surroundings of the AV 110. Further, in some examples, as part of performing the perception, the AV compute process may utilize one or more classifiers (e.g., trained using machine learning (ML)) to identify particular objects. For example, a multi-class classifier may be used to classify each object in the environment of the AV 110 as one of a set of potential objects, e.g., a vehicle, a pedestrian, or a cyclist. As another example, a pedestrian classifier may recognize pedestrians in the environment of the AV 110, a vehicle classifier may recognize vehicles in the environment of the AV 110, etc.

For prediction, the AV compute process may perform predictive analysis on at least some of the recognized objects, e.g., to determine projected pathways of other vehicles, bicycles, and pedestrians. The AV compute process may also predict the AV 110's future trajectories, which may enable the AV 110 to make appropriate navigation decisions. In some examples, the AV compute process may utilize one or more prediction models trained using ML to determine future motions and/or trajectories of other traffic agents and/or of the AV 110 itself.

For AV planning, the AV compute process may plan maneuvers for the AV 110 based on map data, perception data, prediction information, and navigation information, e.g., a route instructed by a fleet management system. In some examples, the AV compute process may also receive map data from a map database (e.g., stored locally at the AV 110 or at a remote server) including data describing roadways such as the roadway system 102 (e.g., locations of roadways, connections between roadways, roadway names, speed limits, traffic flow regulations, toll information, etc.), buildings such as the buildings 118 (e.g., locations of buildings, building geometry, building types), and other objects (e.g., location, geometry, object type). In general, as part of planning, the AV compute process may determine a pathway for the AV 110 to follow. When the AV compute process detects moving objects in the environment of the AV 110, the AV compute process may determine the pathway for the AV 110 based on predicted behaviors of the objects provided by the prediction and right-of-way rules that regulate behavior of vehicles, cyclists, pedestrians, or other objects. The pathway may include locations for the AV 110 to maneuver to, and timing and/or speed of the AV 110 in maneuvering to the locations.

For AV control, the AV compute process may send appropriate commands to instruct movement-related subsystems (e.g., actuators, steering wheel, throttle, brakes, etc.) of the AV 110 to maneuver according to the pathway determined by the planning.

In some examples, the AV 110 may collect sensor data from the sensors, log data computed by the AV compute process, behaviors of the AV 110, and/or driving decisions made by the AV 110 as the AV 110 drives in the real-world driving scene 101. The collected data may be used to generate a road database 120.

According to aspects of the present disclosure, the road database 120 can be used to generate a road data response prediction model 140 to act as a proxy for real-world road data and/or evaluation the performance of an AV simulation. As shown in FIG. 1, a simulation platform 130 may include a feature extraction block 132 and a model fitting block 134. The feature extraction block 132 and the model fitting block 134 may be implemented as software components. The software components can be executed by hardware components (e.g., compute resources such as central processing units (CPUs), graphical processing units (GPUs), storage resources such as memory, network resources, cloud resources) of the simulation platform 130. In some instances, the simulation platform 130 may be similar to the simulation platform 1056 of FIG. 10 and/or the system 1100 of FIG. 11.

The feature extraction block 132 may extract features about the real-world driving scene 101 from the road database 120. The features can be related to objects (e.g., the vehicles 112, the trees 114, the road sign 116, the traffic light 117, the buildings 118, the object 119, a pedestrian, a cyclist, etc.) in the real-world driving scene 101. For instance, the features may include a 3D dimension of an object in a 3D space, a distance from the object to the AV 110, and/or angles associated with an orientation of the object relative to the AV 110. In general, the features can be features of stationary and/or dynamic objects in the real-world driving scene 101. In some examples, the feature extraction block 132 may perform postprocessing to identify object(s) from the road database 120 and then extract features associated with those objects. In other examples, the road database 120 may include labels for respective data, for example, to be used for various training of ML models for AV perception, prediction, and/or planning. For instance, a vehicle in the road database 120 may be attached or associated with a label indicating “vehicle”, a pedestrian in the road database 120 may be attached or associated with a label indicating “pedestrian,” and so on. As such, the feature extract block 132 may leverage the labels without having to perform object identification before feature extraction.

As discussed above, the road database 120 may also include sensor messages (e.g., sensing signals received by physical sensors at the AV 110), an AV drive log, and/or an AV compute log collected by the AV 110. The model fitting block 134 may fit a model over the extracted features and a statistical measure of a respective response. In some examples, the response can be one or more of the sensor messages. In some examples, the response can be associated with the drive log. In some examples, the response can be associated with the compute log. In general, the response can be associated with sensor response(s) or any one or more steps (e.g., perception, prediction, planning, control) performed by an AV compute process at the AV 110. The statistical measure can be any suitable statistical measure, such as a mean, a variance, a percentile, a median, a range, a standard deviation, a total number of certain data points, spatial distribution information, geometric distribution information, etc., depending on the response type. In general, the model fitting block 134 may generate or construct a model to map the extracted features to the statistical measure of the respective response. As shown, the model fitting block 134 may generate a road data response prediction model 140. In some aspects, the road data response prediction model 140 is a statistical model. For instance, the model fitting block 134 may generate the road data response prediction model 140 based on statistical properties of the extracted features and the respective response. In some aspects, the road data response prediction model 140 may be a GLM. A GLM is a flexible generalization of ordinary linear regression. The GLM generalizes linear regression by allowing the linear model to be related to the response variable via a link function and by allowing the magnitude of the variance of each measurement to be a function of its predicted value.

The simulation platform 130 may further include various components to simulate a virtual driving environment for training, developing, and/or testing of an AV compute process or software stack (e.g., perception, prediction, planning, and control). After the AV compute process passes a certain test suite, the AV compute process can be deployed in a real-world vehicle (e.g., the AV 110). As shown in FIG. 1, the simulation platform 130 may include an end-to-end (E2E) AV simulation 151. The E2E AV simulation 151 may include a sensor simulation 150, an AV simulation 154 including an AV compute process 156, and a driving scene renderer 158. The simulation platform 130 may also include memory to store the simulated assets 152 (e.g., trees, buildings, roadside objects, pedestrians, vehicles, cyclists, etc.). The components in the E2E AV simulation 151 may be software components executed by hardware components of the simulation platform 130.

As part of the E2E AV simulation 151, the sensor simulation 150 may simulate various sensors such as cameras, LIDAR sensors, RADAR sensors, etc. The sensor simulation 150 may include models that model the operations of certain sensors. As an example, a simulation model for a particular camera may take one or more objects or a portion of a driving scene as an input and generate an output image. The model may model the colors, the intensities, and/or the dynamic range (e.g., a maximum intensity and a minimum intensity) of the particular camera. As another example, a simulation model for a LIDAR sensor may take one or more objects or a portion of a driving scene as an input and generate LIDAR returns or data points (e.g., a two-dimensional (2D) point cloud or a 3D point cloud). As a further example, a simulation model for a RADAR sensor may take one or more objects or a portion of a driving scene as an input and generate output RADAR returns or data points.

The AV simulation 154 may simulate functionalities and/or operations of the real-world AV 110, and the AV compute process 156 may be substantially the same as the AV compute process that is deployed in the real-world AV 110. For instance, the AV compute process 156 may perform perception, prediction, planning, and control as discussed above.

As part of the E2E AV simulation 151, the driving scene renderer 158 may render a virtual simulated driving scene based on a drive log collected from the reference driving scene 101. For instance, the driving scene renderer 158 may replay a simulation of the real-world driving scene 101 based on the road database 120, for example. Stated differently, the driving scene renderer 158 may generate a virtual driving environment in which the AV simulation 154 executing the AV compute process 156 may drive. In some aspects, the driving scene renderer 158 may place one or more of the simulated assets 152 as part of the rendering. The simulated assets 152 can be generated in a variety of ways, for example, based on images and/or LIDAR data captured from a real-world driving scene. In general, the simulated assets 152 may replicate the sizes (e.g., width, length, height), textures, shapes, and other features of respective objects in a real-world driving scene (e.g., the real-world driving scene 101). The AV compute process 156 may perform perception, prediction, planning, and/or control based on sensor data generated by the sensor simulation 150.

To be able to evaluate the performance of an AV compute process based on a simulation and to obtain the expected performance when the AV compute process is deployed a vehicle for real-world driving, the fidelity of the simulation in replicating a real-world driving scenario and/or the integrity of the simulation is important. According to aspects of the present disclosure, the road data response prediction model 140 can be generated to facilitate the evaluation of at least some of the components in the E2E AV simulation 151.

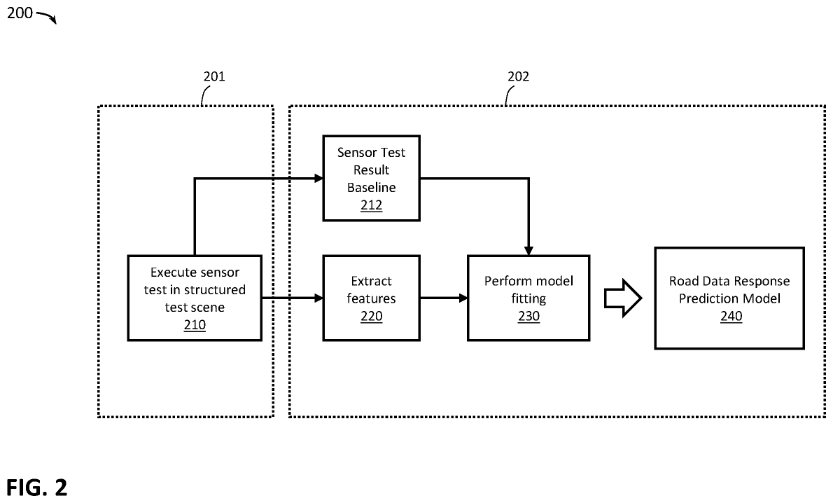

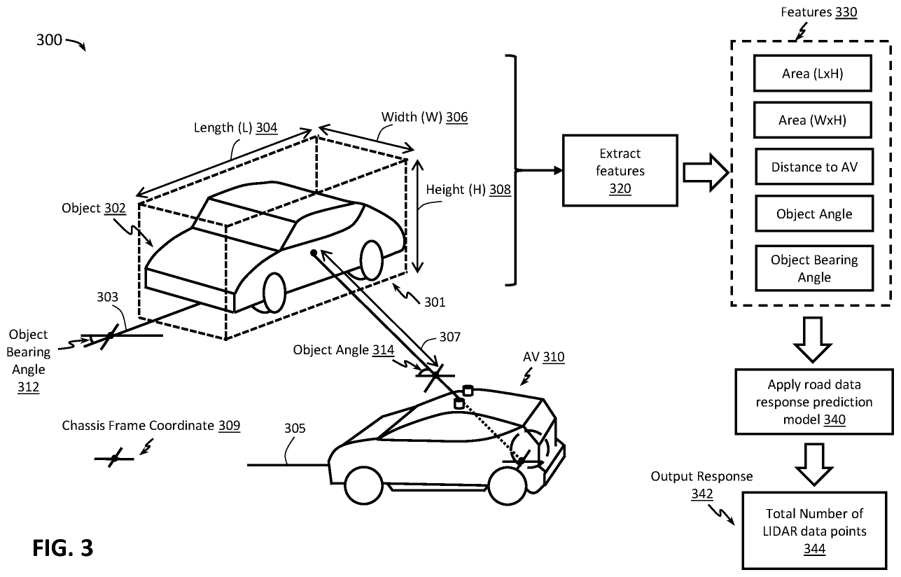

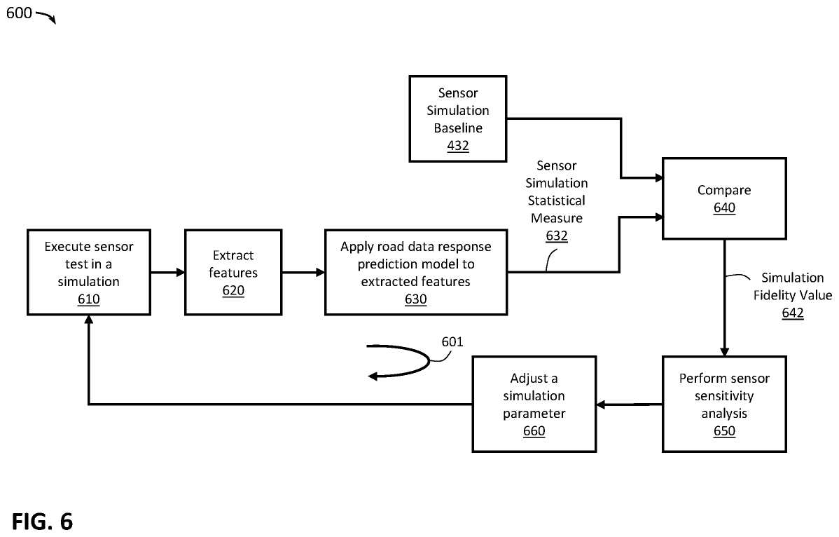

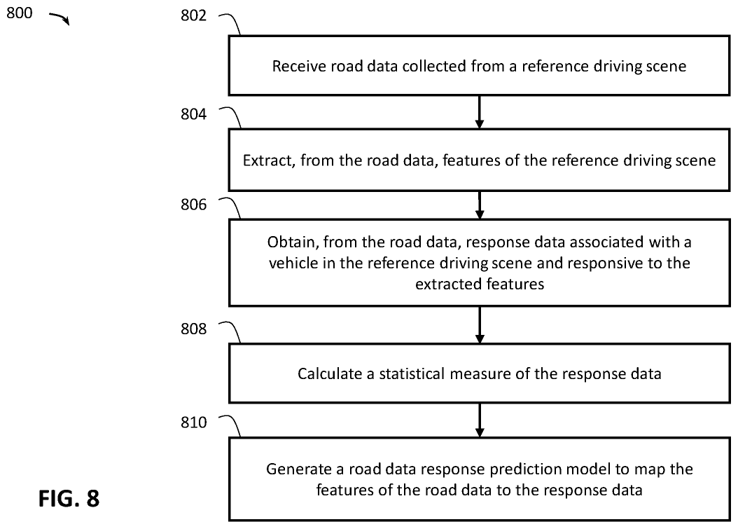

The generations of the road data response prediction model 140 will be discussed more fully below with reference to FIGS. 2 and 8. The road data response prediction model 140 may be used for various purposes. In one example, the road data response prediction model 140 can be used to evaluate the fidelity of a simulation (e.g., one or more components of the E2E AV simulation 151) relative to a real-world driving scene and/or improve the fidelity of the AV simulation as will be discussed more fully below with reference to FIGS. 3-5. In another example, the road data response prediction model 140 can be used to evaluate different versions of AV simulation and/or AV software stack (e.g., AV compute process) as will be discussed more fully below with reference to FIG. 6. In yet another example, the road data response prediction model 140 can be used to operate as a proxy to road data. For instance, the road data response prediction model 140 can provide an estimate or prediction of a statistical measure of a response associated with AV driving for any combination of features within ranges that are modeled by the road data response prediction model 140. While FIGS. 2-6 are discussed in the context of fitting a model to predict statistical properties of LIDAR sensor responses based on road features, the disclosed techniques can be applied to any other components of the simulation 151.

FIGS. 2-7 are discussed in relation to each other to illustrate generation and application of a road data response prediction model (e.g., the road data response prediction model 140). FIG. 2 illustrates a road data response prediction model generation scheme 200, according to some examples of the present disclosure. The scheme 200 may be substantially similar to the scheme 100 and may further provide an example of the response used for the model fitting being a sensor response (e.g., sensor return signals or sensing information). The first part 201 of the scheme 200 may be performed in a real-world driving scene, and the second part 202 of the scheme 200 may be implemented by a computer-implemented system (e.g., the system 1100 of FIG. 11), the simulation platform 130 of FIG. 1, and/or the simulation fidelity measurement block 1057 of FIG. 10.

As shown in FIG. 2, at 210, a sensor test in a structured test scene may be executed. The structured test scene may be based on a certain test case definition for testing in a real-world driving scene (e.g., the real-world driving scene 101). As an example, the structured test scene may include an object (e.g., a vehicle, a pedestrian, a cyclist, etc.) positioned within a field of view of an AV (e.g., the AV 110) under test in a real-world driving scene. The sensor test may include capturing the object using a sensor at the AV. The execution of the sensor test may include collecting sensing information or sensing signals received by the sensor. For instance, the sensor may be a LIDAR sensor, where the LIDAR sensor may send light signals towards the object. Part of the light signals may be reflected by the object and received by the LIDAR sensor in which a point cloud representative of the object may be generated. In an example, a sensor test result baseline 212 may be generated based on the LIDAR point cloud. For instance, the sensor test result baseline 212 may be a statistical measure of the LIDAR data point cloud, e.g., a quantity or a total number of LIDAR data points in the LIDAR point cloud.

At 220, features may be extracted based on the execution of the sensor test (e.g., using the feature extraction block 132). More specifically, features of the object may be extracted from the real-world driving scene. For instance, a 3D bounding box (enclosing the object) may be used to describe a dimension of the object in a 3D space, and thus the features can include a width, a length, height, and/or an area of the 3D bounding box. Additionally or alternatively, the features can include an indication of a distance from the object to the AV in the real-world driving scene. Additionally or alternatively, the features can include an indication of an angle (e.g., an object angle) at which the object is located with respect to the AV in real-world driving scene. Additionally or alternatively, the features can include an indication of an angle (e.g., an object bearing angle) between a path of the object and a path of the vehicle in the reference driving scene. An example of the object being a vehicle and associated features are shown in FIG. 3.

At 230, model fitting may be performed over the extracted features and the sensor test result baseline 212 (e.g., using the model fitting block 134). For instance, as part of the model fitting, a road data response prediction model 240 (e.g., the road data response prediction model 140) may be calculated to map the extracted features to the sensor test result baseline 212. That is, the road data response prediction model 240 may be calculated such that the road data response prediction model 240 may calculate an output approximating the sensor test result baseline 212 (e.g., a statistical measure of a LIDAR point cloud) when given the features extracted from the object as inputs. In some instances, the road data response prediction model 240 may be a GLM.

In some aspects, the road data response prediction model 240 may model various terms associated with the features extracted at 220. For instance, the road data response prediction model 240 may model a linear term for each of one or more of the features. As an example, the features can be represented by F(i)={F1, F2, F3, . . . , Fn}, where i can vary from 1 to n for n number of features. A linear term can be F1, F2, F3, . . . , or Fn. Additionally or alternatively, the road data response prediction model 240 may model linear terms constructed from two or more of the features (e.g., a first term may be F1×F2, a second term may be F1×F3, a third term can be F2×F3, etc.). Additionally or alternatively, the road data response prediction model 240 may model nonlinear terms for one or more of the features (e.g., a first term can be F1 to the power of 2, a second term can be F1 to the power of 3, a third term can be F1 to the power of 4, etc.). In some examples, the road data response prediction model 240 may be a polynomial equation with various terms including the linear terms of any suitable orders and/or nonlinear terms of any suitable orders discussed above. A model fitting may be applied to these terms and model trimming may be applied to remove one or more terms that cause extreme values or outliers with the fitted model.

FIG. 3 illustrates a road data response prediction model application scheme 300, according to some examples of the present disclosure. As shown in FIG. 3, an object 302 (e.g., a vehicle) may be within a field of view of an AV 310 (e.g., the AV 110) under test. Dimensions of the object 302 in a 3D space may be described using a 3D bounding box 301 (shown by the dash-lined box) that encloses the object 302. The 3D bounding box 301 may include a length (L) 304, a width (W) 306, and a height (H) 308. The 3D bounding box 301 may be oriented based on a path 303 (or a trajectory) of the object 302. For instance, the 3D bounding box 301 may be oriented about parallel to the path 303 of the object 302. While FIG. 3 illustrates the object 302 as a vehicle, the scheme 300 may be suitable for use with any object, for example, including but not limited to, pedestrian, cyclist, buildings, trees, or any roadside objects that may be present in a real-world driving scene.

At 320, features of the object 302 may be extracted. The extracted features 330 may include an area (e.g., L×H), an area (W×H), a distance to the AV 310, an object angle, and an object bearing angle. The distance from the object 302 to the AV 310 may refer to a distance between a reference coordinate point of the AV 310 to a reference coordinate point of the object 302 as shown by 307. In the example shown in FIG. 3, the reference coordinate point of the AV 310 may be located at the back axel of the AV 310 and the centroid of the object 302 may correspond to a centroid of a LIDAR point cloud that represents the AV 310. As further shown in FIG. 3, the chassis frame coordinate system 309 of the AV 110 can be used as a reference coordinate system for the angle measurements, where the coordinate system 309 is repeated at multiple locations in FIG. 3 for ease of illustration for various angle measurements. For instance, the object angle is shown by 314, which is an angle at which the object 302 is located with respect to the AV 310. The object bearing angle is shown by 312, which is an angle between the path 303 (or trajectory) of the object 302 and a path 305 (or trajectory) of the AV 310.

At 340, a road data response prediction model (e.g., the road data response prediction model 240) can be applied to the feature to generate an output response 342. The output response 342 may include an indication of a total number of LIDAR data points 344.

Using the 3D dimensions of an object rather the class of the object as part of the features for input to the road data response prediction model can advantageously decouple the road data response prediction model from object types or object classifications. However, for different types and/or makes of sensors, different road data response prediction models similar to the road data response prediction models 140 and/or 240 may be generated.

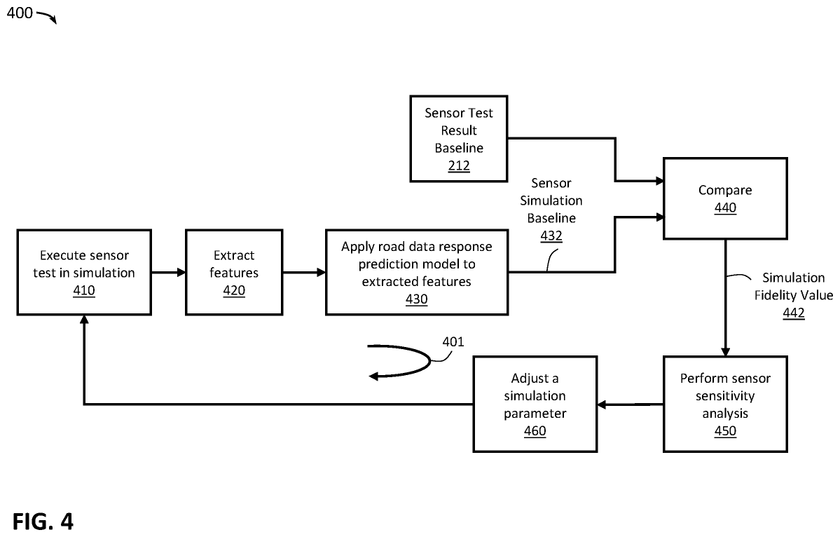

FIG. 4 illustrates a road data response prediction model application scheme 400, according to some examples of the present disclosure; The scheme 400 may be implemented by a computer-implemented system (e.g., the system 1000 of FIG. 10), the simulation platform 130 of FIG. 1, and/or the simulation fidelity measurement block 1057 of FIG. 10. The scheme 400 illustrates an application of the road data response prediction model 240 to evaluate and/or improve the performance of a simulation (e.g., any one or more of the components in the E2E AV simulation 151 of FIG. 1) related to AV performance.

As shown in FIG. 4, at 410, a sensor test may be executed in a simulation. To this end, a sensor simulation (e.g., the sensor simulation 150) may simulate or model the operations of a particular sensor used by a real-world AV (e.g., the AV 110), and the sensor test may include executing the sensor simulation according to a certain test case definition. In some examples, the test case definition may be the same as the test case definition used for generating the sensor test result baseline 212 to which the sensor simulation may be compared (e.g., at 440). That is, the sensor test may be configured using similar mechanisms as discussed above at 210 of FIG. 2. For instance, the simulation may simulate a test scene including a simulated object at a field of view of a simulated AV (equipped with simulated sensors).

At 420, features may be extracted based on the execution of the sensor test (in the simulation). The features may be similar to the features discussed above at 220 of FIG. 2. For instance, the features may include dimensions of the simulated object in a 3D space, a distance from the simulated object to the AV, an object angle, and/or an object bearing angle of the simulated object with respect to the AV, for example, similar to the features 330 discussed above with reference to FIG. 3.

At 430, a road data response prediction model (e.g., the road data response prediction model 240) may be applied to the extracted features. That is, the features may be input to the road data response prediction model, and the road data response prediction model may process the features to generate a predicted statistical measure of a response, where the predicted statistical measure may be referred to as a sensor simulation baseline 432. Referring to the example discussed above where the sensor test may be a LIDAR sensor test in simulation, the sensor simulation baseline 432 may include an indication of a total number of LIDAR data points.

At 440, the sensor simulation baseline 432 may be compared to the sensor test result baseline 212 to generate a simulation fidelity value 442 (e.g., a fidelity score). That is, the predicted total number of LIDAR data points output by the road data response prediction model in response to the features extracted at 420 may be compared to the total number of LIDAR data points in a LIDAR point cloud received by a sensor of an AV in a real-world driving scene responsive to an object having similar features.

As further shown in FIG. 4, the scheme 400 may include a feedback loop 401, where the simulation fidelity value 442 can be used to analyze factors that may impact the fidelity of the sensor simulation and/or to improve the fidelity of the sensor simulation. In this regard, at 450, sensor sensitivity analysis can be performed. For instance, the analysis can determine which of the input factors (e.g., the extracted features) may impact the fit of simulation data (e.g., the statistical measure of a sensor response) to the road data response prediction model the most.

At 460, based on the analysis at 450, a simulation parameter can be adjusted for the simulation. For instance, the simulation parameter can be related to the sensor simulation and/or the features of the simulated objects. In general, the simulation parameter can be adjusted iteratively based on a comparison between the statistical measure of the sensor test result baseline 212 (e.g., a reference sensor response statistical measure) and a sensor response statistical measure predicted by the road data response prediction model in a previous iteration. In some examples, the loop 401 can be performed iteratively until the simulation data fits to the road data response prediction model sufficiently well. For example, if the comparison at 440 indicates that a difference in the total number of LIDAR data points between the simulation and the sensor test result baseline 212 is greater than a certain threshold, the loop 401 may be repeated. In other examples, the loop 401 can be optional.

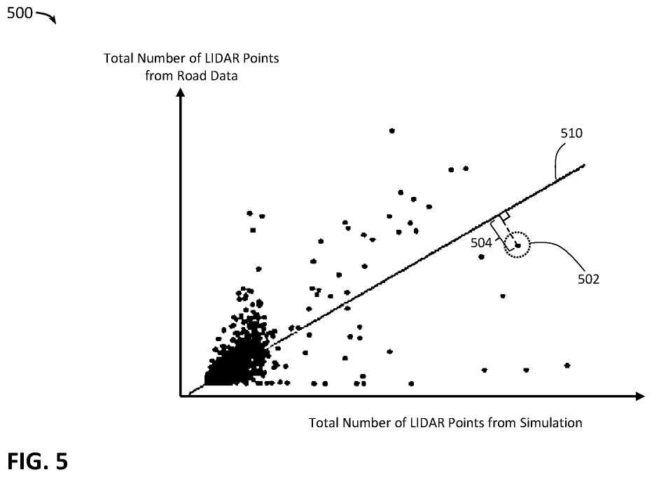

FIG. 5 is a graph 500 of observed sensor response statistics from a real-world driving scene versus sensor response statistics from a simulation (e.g., the sensor simulation 150 of FIG. 1, the simulation executed at 210 of FIG. 2 and/or at 410 of FIG. 4), according to some examples of the present disclosure. In FIG. 5, the x-axis may represent a total number of LIDAR data points obtained from simulation (e.g., by performing the operations of 410-430 of FIG. 4) in units of count, and the y-axis may represent a total number of LIDAR data points obtained from road data (e.g., the road database 120) in units of count.

The graph 500 may be generated by executing sensor test in structured test scenes in a real physical world (e.g., similar to the execution at 210 of FIG. 2) and executing sensor test in a simulation (e.g., similar to the execution at 410 of FIG. 4). The features (e.g., the object 3D bounding box dimensions, the distances to AV, the object angles, and the object bearing angles) can be varied, for example, each within a certain defined range. The real-world sensor test and the simulation sensor test can be executed for each test case (defining a combination of the features with various values). In the graph 500, each black dot may represent a total number of LIDAR data points calculated from the real-world sensor test vs a total number of LIDAR data points calculated from the simulation sensor test for the same set of feature values.

When the total number of LIDAR data points calculated from the simulation sensor test matches the total number of LIDAR data points calculated from the real-world sensor test, the corresponding dot may lie on the line 510 (e.g., a 45-degree line). Thus, the dots that are off the line 510 are outliers in which the total number of LIDAR data points calculated from the simulation sensor test does not match total number of LIDAR data points calculated from the real-world sensor test. An example of an outlier is shown by 502. As such, in some examples, a perpendicular distance from a dot to the line 510 may be used an indicator of a fidelity of the sensor simulation. An example of a perpendicular distance from the outlier 502 to the line 510 is shown by 504.

FIG. 6 illustrates a road data response prediction model application scheme 600, according to some examples of the present disclosure. The scheme 600 may be implemented by a computer-implemented system (e.g., the system 1100 of FIG. 11), the simulation platform 130 of FIG. 1, and/or the simulation fidelity measurement block 1057 of FIG. 10. The scheme 600 illustrates an application of the road data response prediction model 240 to evaluate the performance of different versions of simulation (e.g., any one or more of the components in the E2E AV simulation 151 of FIG. 1).

Generally speaking, the scheme 600 includes features similar to scheme 400 in many respects. For example, operations at 610, 620, 630, 640, 650, and 660 are similar to operations at 410, 420, 430, 440, 450, and 460, respectively; for brevity, a discussion of these elements is not repeated, and these operations may take the form of any of the embodiments discussed above with reference to FIG. 4.

To compare different code versions of simulations, at 610, a sensor test may be executed in a simulation (e.g., an updated simulation code with a code version A). For example, at 620, features can be extracted from the execution at 610 (e.g., using similar mechanisms as at 420). At 630, the road data response prediction model (e.g., the road data response prediction model 240) can be applied to the features extracted at 620 to obtain a predicted sensor simulation statistical measure 632. The predicted sensor simulation statistical measure 632 may include an indicator of a total number of LIDAR data points in a LIDAR point cloud responsive to the extracted features. At 640, the predicted sensor simulation statistical measure 632 can be compared to the sensor simulation baseline 432 of FIG. 4 to generate a simulation fidelity value 642 for the new simulation code. Similar to the scheme 400, the scheme 600 may include a feedback loop 601 in which the sensor sensitivity for the new simulation code version A can be analyzed at 650, and a simulation parameter of the new simulation code version A can be adjusted based on the comparison at 640. In an example, if the comparison at 640 indicates that a difference in the total number of LIDAR data points between the sensor simulation baseline 432 and the new simulation code version A is greater than a certain threshold, the loop 601 may be repeated. In other examples, the loop 601 can be optional.

Using the road data response prediction model to evaluate a new version of a simulation code with respect to a simulation baseline code instead of running a full test suite for the new simulation code (which can take 5, 10, 20, 30 or more hours depending on the number of test cases in the suite) can advantageously reduce the amount of test time and/or cost and yet providing a fidelity (or a performance) measure for the new simulation code (e.g., prior to code integration and/or release).

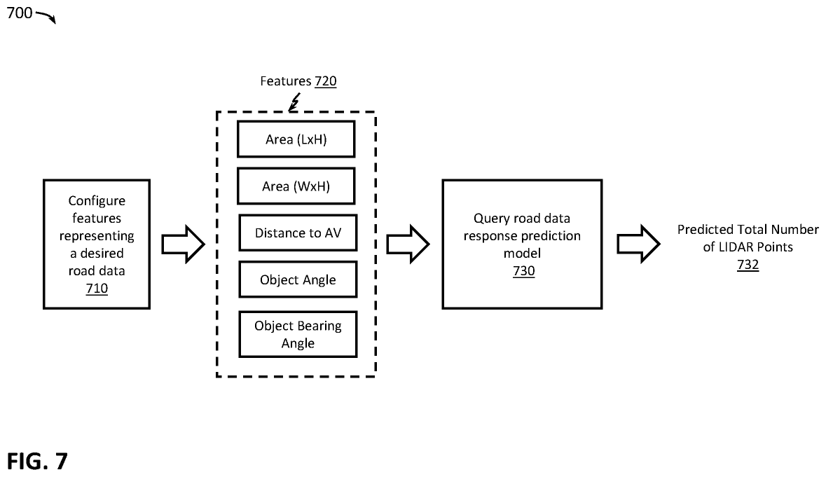

FIG. 7 illustrates a road data response prediction model application scheme 700, according to some examples of the present disclosure. The scheme 700 may be implemented by a computer-implemented system (e.g., the system 1100 of FIG. 11), the simulation platform 130 of FIG. 1, and/or the simulation fidelity measurement block 1057 of FIG. 10. The scheme 700 illustrates an application of the road data response prediction model 240 to provide an estimate or prediction of a statistical measure of a response associated with AV driving for any combination of features within ranges that are modeled by the road data response prediction model 240.

As shown in FIG. 7, at 710, features representing a desired road data (e.g., an object) may be configured. For instance, the features for the configuration are shown by 720, which may be substantially similar to the features discussed above with reference to FIG. 3. For instance, the desired road data object may have certain dimensions in a 3D space described by a 3D bounding box (e.g., similar to the 3D bounding box 301). The 3D bounding box may include a height (H), a length (L), and a width (W). The features 720 may include an area calculated from L×H, an area calculated from W×H, a distance to an AV, an object angle (an angle at which the object is located with respect to the AV, and/or an object bearing angle (an angle between a path of the object and a path of the AV). The configuration at 710 may include assigning a value to each of the features 720, where the value may be within a respective range for which the road data response prediction model is trained or generated (e.g., in the scheme 200)

Subsequently, at 730, a road data response prediction model (e.g., the road data response prediction model 240) may be queried based on the features 730, and the road data response prediction model may output a predicted total number of LIDAR points for an object with the features 730. That is, the scheme 700 can predict a total number of LIDAR data points for an object that has not been captured in the real-world. As an example, sensing information captures in a real-world may include captures for objects at 5 meters (m), 8 m, 15 m away from an AV but not for an object at 12 m away from an AV. The road data response prediction model can be configured to predict a total number of LIDAR data points for an object that is at 12 m away from an AV. As another example, sensing information captures in a real-world may include captures for objects with heights of 0.2 m, 0.8 m, 1.5 m, and 2.5 m but not for an object with a height of 1.2 m. The road data response prediction model can be configured to predict a total number of LIDAR data points for an object with a height of 1.2 m.

FIG. 8 illustrates a road data response prediction model application process 800, according to some examples of the present disclosure. The process 800 can be implemented by a computer-implemented system such as the simulation platform 130 of FIG. 1, the simulation fidelity measurement block 1057 of FIG. 10, and/or the system 1100 of FIG. 11. In general, the process 800 may be performed using any suitable hardware components and/or software components. The process 800 may utilize similar mechanisms discussed above with reference to FIGS. 1-7. Operations are illustrated once each and in a particular order in FIG. 8, but the operations may be performed in parallel, reordered, and/or repeated as desired.

At 802, the computer-implemented system may receive road data collected from a reference driving scene. In some examples, the reference driving scene may be a real-world driving scene (e.g., the real-world driving scene 101) in the physical world. In other examples, the reference driving scene can be a high-fidelity simulated driving scene.

At 804, the computer-implemented system may extract, from the road data, features of the reference driving scene. In some aspects, the features may be associated with an object. For instance, the extracted features may include an indication of a dimension of the object. For instance, the extracted features may include a length, a width, a height, an area of the object (e.g., within a 3D bounding box), a distance from the object to the vehicle in the reference driving scene, an angle (e.g., object angle) at which the object is located with respect to the vehicle in the reference driving scene, and/or an angle (e.g., an object bearing angle) between a path of the object and a path of the vehicle in the reference driving scene, for example, as discussed above with reference to FIG. 3.

At 806, the computer-implemented system may obtain, from the road data, response data associated with a vehicle in the reference driving scene and responsive to the extracted features. In some aspects, the response data may include sensing information received by a sensor (e.g., a LIDAR sensor) at the vehicle. The sensing information may be responsive to the reference driving scene, for example, capturing a representation of an object in the reference driving scene. In some aspects, the response data may include e a LIDAR point cloud responsive to an object in the reference driving scene.

At 808, the computer-implemented system may calculate a statistical measure of the response data. The statistical measure can be a mean, a variance, a percentile, a median, a range, a standard deviation, a total number of certain data points, spatial distribution information, geometric distribution information, etc., for example, depending on the response data type. In some aspects, when the response data is a LIDAR point cloud, the statistical measure may include an indication of a quantity (a total number) of LIDAR data points in the LIDAR point cloud.

At 810, the computer-implemented system may generate a road data response prediction model to map the extracted features of the road data to the statistical measure of the response data. In some aspects, the road data response prediction model may model at least one of a linear term associated with a single feature of the extracted features, a linear term associated with at least two features of the extracted features, or a nonlinear term associated with one or more features of the extracted features. As an example, the features can be represented by F(i)={F1, F2, F3, . . . , Fn}, where i can vary from 1 to n for n number of features. In such an example, a linear term can be F(i), F(i)×F(i+k), where k can be 1 to (n−1), and a nonlinear term can be F(i)\hat{ }m, where m can be any integer value greater than 1. In some aspects, the road data response prediction model is a GLM.

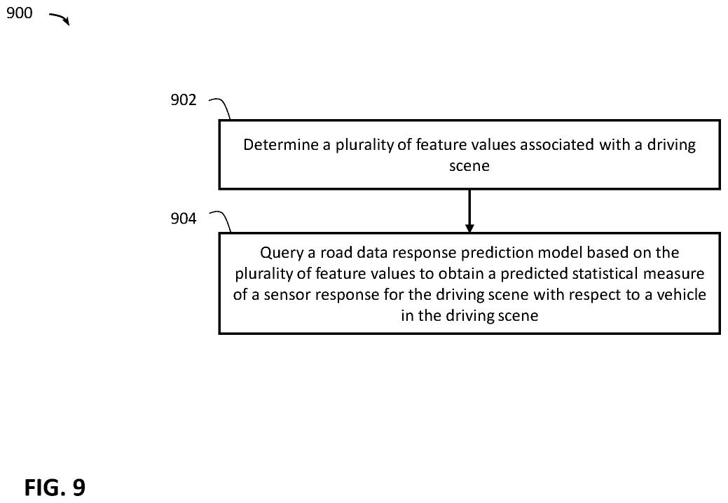

FIG. 9 illustrates a road data response prediction model application process 900, according to some examples of the present disclosure. The process 900 can be implemented by a computer-implemented system such as the simulation platform 130 of FIG. 1, the simulation fidelity measurement block 1057 of FIG. 10, and/or the system 1100 of FIG. 11. In general, the process 900 may be performed using any suitable hardware components and/or software components. The process 900 may utilize similar mechanisms discussed above with reference to FIGS. 1-7. Operations are illustrated once each and in a particular order in FIG. 9, but the operations may be performed in parallel, reordered, and/or repeated as desired.

At 902, the computer-implemented system may determine a plurality of feature values associated with a driving scene. In some aspects, the features may include dimensions (e.g., a length, a height, a width) of an object in the driving scene, a distance between an object and the vehicle in the driving scene, an angle of a location of the object with respect to the vehicle, and/or an angle of a path of the object with respect to the vehicle. In some examples, the dimensions of the object may be represented a 3D bounding box in which the object is enclosed.

At 904, the computer-implemented system may query a road data response prediction model based on the plurality of feature values to obtain a predicted statistical measure of a sensor response for the driving scene with respect to a vehicle in the driving scene. The predicted statistical measure of the sensor response may include a predicted number of LIDAR data points responsive to the driving scene.

In some aspects, the computer-implemented system may further execute a sensor test in a simulation that simulates the driving scene. The determining of the plurality of features at 902 may include extracting the features from the simulation. The computer-implemented system may further determine a fidelity of the simulation based on a comparison between a statistical measure of a reference sensor response and the predicted statistical measure of the sensor response obtained from the querying. In some examples, the statistical measure for the reference sensor response may be a statistical measure of a real-world physical sensor response, for example, as discussed above with reference to FIG. 4. In other examples, the statistical measure for the reference sensor response may be a statistical measure predicted for a sensor simulation, for example, as discussed above with reference to FIG. 4. In some aspects, the computer-implemented system may further adjust a parameter of the simulation based on a comparison between the statistical measure of the reference sensor response and a previous predicted statistical measure of a sensor response, where the executing the sensor test may be based on the adjustment. In other words, the computer-implemented system may iteratively adjust a parameter of the simulation based on a comparison between the reference sensor response statistical measure and a predicted sensor response statistical measure predicted by the road data response prediction model in a previous iteration, for example, as discussed above with reference to the loop 401 in FIG. 4 and/or the loop 601 in FIG. 6.

Turning now to FIG. 10, this figure illustrates an example of an AV management system 1000. One of ordinary skill in the art will understand that, for the AV management system 1000 and any system discussed in the present disclosure, there may be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 1000 includes an AV 1002, a data center 1050, and a client computing device 1070. The AV 1002, the data center 1050, and the client computing device 1070 may communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 1002 may navigate about roadways without a human driver based on sensor signals generated by multiple sensor systems 1004, 1006, and 1008. The sensor systems 1004-1008 may include different types of sensors and may be arranged about the AV 1002. For instance, the sensor systems 1004-1008 may comprise Inertial Measurement Units (IMUs), cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 1004 may be a camera system, the sensor system 1006 may be a LIDAR system, and the sensor system 1008 may be a RADAR system. Other embodiments may include any other number and type of sensors.

AV 1002 may also include several mechanical systems that may be used to maneuver or operate AV 1002. For instance, the mechanical systems may include vehicle propulsion system 1030, braking system 1032, steering system 1034, safety system 1036, and cabin system 1038, among other systems. Vehicle propulsion system 1030 may include an electric motor, an internal combustion engine, or both. The braking system 1032 may include an engine brake, a wheel braking system (e.g., a disc braking system that utilizes brake pads), hydraulics, actuators, and/or any other suitable componentry configured to assist in decelerating AV 1002. The steering system 1034 may include suitable componentry configured to control the direction of movement of the AV 1002 during navigation. Safety system 1036 may include lights and signal indicators, a parking brake, airbags, and so forth. The cabin system 1038 may include cabin temperature control systems, in-cabin entertainment systems, and so forth. In some embodiments, the AV 1002 may not include human driver actuators (e.g., steering wheel, handbrake, foot brake pedal, foot accelerator pedal, turn signal lever, window wipers, etc.) for controlling the AV 1002. Instead, the cabin system 1038 may include one or more client interfaces (e.g., Graphical User Interfaces (GUIs), Voice User Interfaces (VUIs), etc.) for controlling certain aspects of the mechanical systems 1030-1038.

AV 1002 may additionally include a local computing device 1010 that is in communication with the sensor systems 1004-1008, the mechanical systems 1030-1038, the data center 1050, and the client computing device 1070, among other systems. The local computing device 1010 may include one or more processors and memory, including instructions that may be executed by the one or more processors. The instructions may make up one or more software stacks or components responsible for controlling the AV 1002; communicating with the data center 1050, the client computing device 1070, and other systems; receiving inputs from riders, passengers, and other entities within the AV's environment; logging metrics collected by the sensor systems 1004-1008; and so forth. In this example, the local computing device 1010 includes a perception stack 1012, a mapping and localization stack 1014, a planning stack 1016, a control stack 1018, a communications stack 1020, an High Definition (HD) geospatial database 1022, and an AV operational database 1024, among other stacks and systems.

Perception stack 1012 may enable the AV 1002 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 1004-1008, the mapping and localization stack 1014, the HD geospatial database 1022, other components of the AV, and other data sources (e.g., the data center 1050, the client computing device 1070, third-party data sources, etc.). The perception stack 1012 may detect and classify objects and determine their current and predicted locations, speeds, directions, and the like. In addition, the perception stack 1012 may determine the free space around the AV 1002 (e.g., to maintain a safe distance from other objects, change lanes, park the AV, etc.). The perception stack 1012 may also identify environmental uncertainties, such as where to look for moving objects, flag areas that may be obscured or blocked from view, and so forth.

Mapping and localization stack 1014 may determine the AV's position and orientation (pose) using different methods from multiple systems (e.g., GPS, IMUs, cameras, LIDAR, RADAR, ultrasonic sensors, the HD geospatial database 1022, etc.). For example, in some embodiments, the AV 1002 may compare sensor data captured in real-time by the sensor systems 1004-1008 to data in the HD geospatial database 1022 to determine its precise (e.g., accurate to the order of a few centimeters or less) position and orientation. The AV 1002 may focus its search based on sensor data from one or more first sensor systems (e.g., GPS) by matching sensor data from one or more second sensor systems (e.g., LIDAR). If the mapping and localization information from one system is unavailable, the AV 1002 may use mapping and localization information from a redundant system and/or from remote data sources.

The planning stack 1016 may determine how to maneuver or operate the AV 1002 safely and efficiently in its environment. For example, the planning stack 1016 may receive the location, speed, and direction of the AV 1002, geospatial data, data regarding objects sharing the road with the AV 1002 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 1002 from one point to another. The planning stack 1016 may determine multiple sets of one or more mechanical operations that the AV 1002 may perform (e.g., go straight at a specified speed or rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 1016 may select from multiple backup plans to carry out. For example, while preparing to change lanes to turn right at an intersection, another vehicle may aggressively cut into the destination lane, making the lane change unsafe. The planning stack 1016 could have already determined an alternative plan for such an event, and upon its occurrence, help to direct the AV 1002 to go around the block instead of blocking a current lane while waiting for an opening to change lanes.

The control stack 1018 may manage the operation of the vehicle propulsion system 1030, the braking system 1032, the steering system 1034, the safety system 1036, and the cabin system 1038. The control stack 1018 may receive sensor signals from the sensor systems 1004-1008 as well as communicate with other stacks or components of the local computing device 1010 or a remote system (e.g., the data center 1050) to effectuate operation of the AV 1002. For example, the control stack 1018 may implement the final path or actions from the multiple paths or actions provided by the planning stack 1016. Implementation may involve turning the routes and decisions from the planning stack 1016 into commands for the actuators that control the AV's steering, throttle, brake, and drive unit.

The communication stack 1020 may transmit and receive signals between the various stacks and other components of the AV 1002 and between the AV 1002, the data center 1050, the client computing device 1070, and other remote systems. The communication stack 1020 may enable the local computing device 1010 to exchange information remotely over a network, such as through an antenna array or interface that may provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 1020 may also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 1022 may store HD maps and related data of the streets upon which the AV 1002 travels. In some embodiments, the HD maps and related data may comprise multiple layers, such as an areas layer, a lanes and boundaries layer, an intersections layer, a traffic controls layer, and so forth. The areas layer may include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer may include geospatial information of road lanes (e.g., lane or road centerline, lane boundaries, type of lane boundaries, etc.) and related attributes (e.g., direction of travel, speed limit, lane type, etc.). The lanes and boundaries layer may also include 3D attributes related to lanes (e.g., slope, elevation, curvature, etc.). The intersections layer may include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer may include geospatial information of traffic signal lights, traffic signs, and other road objects and related attributes.

The AV operational database 1024 may store raw AV data generated by the sensor systems 1004-1008 and other components of the AV 1002 and/or data received by the AV 1002 from remote systems (e.g., the data center 1050, the client computing device 1070, etc.). In some embodiments, the raw AV data may include HD LIDAR point cloud data, image or video data, RADAR data, GPS data, and other sensor data that the data center 1050 may use for creating or updating AV geospatial data as discussed further below with respect to FIG. 5 and elsewhere in the present disclosure.

The data center 1050 may be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 1050 may include one or more computing devices remote to the local computing device 1010 for managing a fleet of AVs and AV-related services. For example, in addition to managing the AV 1002, the data center 1050 may also support a ridesharing service, a delivery service, a remote/roadside assistance service, street services (e.g., street mapping, street patrol, street cleaning, street metering, parking reservation, etc.), and the like.

The data center 1050 may send and receive various signals to and from the AV 1002 and the client computing device 1070. These signals may include sensor data captured by the sensor systems 1004-1008, roadside assistance requests, software updates, ridesharing pick-up and drop-off instructions, and so forth. In this example, the data center 1050 includes one or more of a data management platform 1052, an Artificial Intelligence/Machine Learning (AI/ML) platform 1054, a simulation platform 1056, a remote assistance platform 1058, a ridesharing platform 1060, and a map management platform 1062, among other systems.

Data management platform 1052 may be a “big data” system capable of receiving and transmitting data at high speeds (e.g., near real-time or real-time), processing a large variety of data, and storing large volumes of data (e.g., terabytes, petabytes, or more of data). The varieties of data may include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 1050 may access data stored by the data management platform 1052 to provide their respective services.

The AI/ML platform 1054 may provide the infrastructure for training and evaluating machine learning algorithms for operating the AV 1002, the simulation platform 1056, the remote assistance platform 1058, the ridesharing platform 1060, the map management platform 1062, and other platforms and systems. Using the AI/ML platform 1054, data scientists may prepare data sets from the data management platform 1052; select, design, and train machine learning models; evaluate, refine, and deploy the models; maintain, monitor, and retrain the models; and so on.

The simulation platform 1056 may enable testing and validation of the algorithms, machine learning models, neural networks, and other development efforts for the AV 1002, the remote assistance platform 1058, the ridesharing platform 1060, the map management platform 1062, and other platforms and systems. The simulation platform 1056 may replicate a variety of driving environments and/or reproduce real-world scenarios from data captured by the AV 1002, including rendering geospatial information and road infrastructure (e.g., streets, lanes, crosswalks, traffic lights, stop signs, etc.) obtained from the map management platform 1062; modeling the behavior of other vehicles, bicycles, pedestrians, and other dynamic elements; simulating inclement weather conditions, different traffic scenarios; and so on. In some embodiments, the simulation platform 1056 may include a simulation fidelity measurement block 1057 that generates a road data response prediction model (e.g., similar to the road data response prediction models 140 and/or 240) and applies the road data response prediction model as discussed herein.

The remote assistance platform 1058 may generate and transmit instructions regarding the operation of the AV 1002. For example, in response to an output of the AI/ML platform 1054 or other system of the data center 1050, the remote assistance platform 1058 may prepare instructions for one or more stacks or other components of the AV 1002.

The ridesharing platform 1060 may interact with a customer of a ridesharing service via a ridesharing application 1072 executing on the client computing device 1070. The client computing device 1070 may be any type of computing system, including a server, desktop computer, laptop, tablet, smartphone, smart wearable device (e.g., smart watch; smart eyeglasses or other Head-Mounted Display (HMD); smart ear pods or other smart in-ear, on-ear, or over-ear device; etc.), gaming system, or other general purpose computing device for accessing the ridesharing application 1072. The client computing device 1070 may be a customer's mobile computing device or a computing device integrated with the AV 1002 (e.g., the local computing device 1010). The ridesharing platform 1060 may receive requests to be picked up or dropped off from the ridesharing application 1072 and dispatch the AV 1002 for the trip.

Map management platform 1062 may provide a set of tools for the manipulation and management of geographic and spatial (geospatial) and related attribute data. The data management platform 1052 may receive LIDAR point cloud data, image data (e.g., still image, video, etc.), RADAR data, GPS data, and other sensor data (e.g., raw data) from one or more AVs 1002, Unmanned Aerial Vehicles (UAVs), satellites, third-party mapping services, and other sources of geospatially referenced data. The raw data may be processed, and map management platform 1062 may render base representations (e.g., tiles (2D), bounding volumes (3D), etc.) of the AV geospatial data to enable users to view, query, label, edit, and otherwise interact with the data. Map management platform 1062 may manage workflows and tasks for operating on the AV geospatial data. Map management platform 1062 may control access to the AV geospatial data, including granting or limiting access to the AV geospatial data based on user-based, role-based, group-based, task-based, and other attribute-based access control mechanisms. Map management platform 1062 may provide version control for the AV geospatial data, such as to track specific changes that (human or machine) map editors have made to the data and to revert changes when necessary. Map management platform 1062 may administer release management of the AV geospatial data, including distributing suitable iterations of the data to different users, computing devices, AVs, and other consumers of HD maps. Map management platform 1062 may provide analytics regarding the AV geospatial data and related data, such as to generate insights relating to the throughput and quality of mapping tasks.

In some embodiments, the map viewing services of map management platform 1062 may be modularized and deployed as part of one or more of the platforms and systems of the data center 1050. For example, the AI/ML platform 1054 may incorporate the map viewing services for visualizing the effectiveness of various object detection or object classification models, the simulation platform 1056 may incorporate the map viewing services for recreating and visualizing certain driving scenarios, the remote assistance platform 1058 may incorporate the map viewing services for replaying traffic incidents to facilitate and coordinate aid, the ridesharing platform 1060 may incorporate the map viewing services into the client application 1072 to enable passengers to view the AV 1002 in transit en route to a pick-up or drop-off location, and so on.

FIG. 11 illustrates an example processor-based system with which some aspects of the subject technology may be implemented. For example, processor-based system 1100 may be any computing device making up, or any component thereof in which the components of the system are in communication with each other using connection 1105. Connection 1105 may be a physical connection via a bus, or a direct connection into processor 1110, such as in a chipset architecture. Connection 1105 may also be a virtual connection, networked connection, or logical connection.

In some embodiments, computing system 1100 is a distributed system in which the functions described in this disclosure may be distributed within a datacenter, multiple data centers, a peer network, etc. In some embodiments, one or more of the described system components represents many such components each performing some or all of the function for which the component is described. In some embodiments, the components may be physical or virtual devices.

Example system 1100 includes at least one processing unit (Central Processing Unit (CPU) or processor) 1110 and connection 1105 that couples various system components including system memory 1115, such as Read-Only Memory (ROM) 1120 and Random-Access Memory (RAM) 1125 to processor 1110. Computing system 1100 may include a cache of high-speed memory 1112 connected directly with, in close proximity to, or integrated as part of processor 1110.

Processor 1110 may include any general-purpose processor and a hardware service or software service, such as a road data response prediction model 1132 (e.g., similar to the road data response prediction model 140 and/or 240) and a simulation fidelity measurement block 1136 stored in storage device 1130, configured to control processor 1110 as well as a special-purpose processor where software instructions are incorporated into the actual processor design. The simulation fidelity measurement block 1136 may calculate a fidelity value for a simulation using the road data response prediction model 1132 as discussed herein. Processor 1110 may essentially be a completely self-contained computing system, containing multiple cores or processors, a bus, memory controller, cache, etc. A multi-core processor may be symmetric or asymmetric.

To enable user interaction, computing system 1100 includes an input device 1145, which may represent any number of input mechanisms, such as a microphone for speech, a touch-sensitive screen for gesture or graphical input, keyboard, mouse, motion input, speech, etc. Computing system 1100 may also include output device 1135, which may be one or more of a number of output mechanisms known to those of skill in the art. In some instances, multimodal systems may enable a user to provide multiple types of input/output to communicate with computing system 1100. Computing system 1100 may include communications interface 1140, which may generally govern and manage the user input and system output. The communication interface may perform or facilitate receipt and/or transmission wired or wireless communications via wired and/or wireless transceivers, including those making use of an audio jack/plug, a microphone jack/plug, a Universal Serial Bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, Wireless Local Area Network (WLAN) signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 1140 may also include one or more Global Navigation Satellite System (GNSS) receivers or transceivers that are used to determine a location of the computing system 1100 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1130 may be a non-volatile and/or non-transitory and/or computer-readable memory device and may be a hard disk or other types of computer readable media which may store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Atatic RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L #), Resistive RAM (RRAM/ReRAM), Phase Change Memory (PCM), Spin Transfer Torque RAM (STT-RAM), another memory chip or cartridge, and/or a combination thereof.

Storage device 1130 may include software services, servers, services, etc., that when the code that defines such software is executed by the processor 1110, it causes the system 1100 to perform a function. In some embodiments, a hardware service that performs a particular function may include the software component stored in a computer-readable medium in connection with the necessary hardware components, such as processor 1110, connection 1105, output device 1135, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices may be any available device that may be accessed by a general-purpose or special purpose computer, including the functional design of any special purpose processor as described above. By way of example, and not limitation, such tangible computer-readable devices may include RAM, ROM, EEPROM, CD-ROM or other optical disk storage, magnetic disk storage or other magnetic storage devices, or any other device which may be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

### Selected Examples

Example 1 includes a computer-implemented system, including one or more non-transitory computer-readable media storing instructions, when executed by one or more processing units, cause the one or more processing units to perform operations including receiving road data collected from a reference driving scene; extracting, from the road data, features of the reference driving scene; obtaining, from the road data, response data associated with a vehicle in the reference driving scene and responsive to the extracted features; calculating a statistical measure of the response data; and generating a road data response prediction model to map the extracted features of the road data to the statistical measure of the response data.

In Example 2, the computer-implemented system of example 1 can optionally include where the response data includes sensing information associated with the reference driving scene; and the generating the road data response prediction model includes generating the road data response prediction model to map the extracted features to the statistical measure of the sensing information.

In Example 3, the computer-implemented system of any one of examples 1-2 can optionally include where the statistical measure includes an indication of a quantity of light detection and ranging (LIDAR) data points responsive to an object in the reference driving scene.

In Example 4, the computer-implemented system of any one of examples 1-3 can optionally include where the object includes at least one of a vehicle, a pedestrian, or a cyclist.

In Example 5, the computer-implemented system of any one of examples 1-4 can optionally include where the extracted features include an indication of a dimension of the object.

In Example 6, the computer-implemented system of any one of examples 1-5 can optionally include where the extracted features include an indication of a distance from the object to the vehicle in the reference driving scene.

In Example 7, the computer-implemented system of any one of examples 1-6 can optionally include where the extracted features include an indication of an angle at which the object is located with respect to the vehicle in the reference driving scene.

In Example 8, the computer-implemented system of any one of examples 1-7 can optionally include where the extracted features include an indication of an angle between a path of the object and a path of the vehicle in the reference driving scene.

In Example 9, the computer-implemented system of any one of examples 1-8 can optionally include where the road data response prediction model models at least one of a linear term associated with a single feature of the extracted features; a linear term associated with at least two features of the extracted features; or a nonlinear term associated with one or more features of the extracted features.

In Example 10, the computer-implemented system of any one of examples 1-9 can optionally include where the road data response prediction model is a generalized linear model (GLM).

Example 11 includes a computer-implemented system, including one or more non-transitory computer-readable media storing instructions, when executed by one or more processing units, cause the one or more processing units to perform operations including determining a plurality of feature values associated with a driving scene; and applying a road data response prediction model to the plurality of feature values to obtain a predicted statistical measure of a sensor response for the driving scene with respect to a vehicle in the driving scene.

In Example 12, the computer-implemented system of example 11 can optionally include where the plurality of feature values are associated with an object in the driving scene.

In Example 13, the computer-implemented system of any one of examples 11-12 can optionally include where the predicted statistical measure of the sensor response includes an indication of a predicted number of light detection and ranging (LIDAR) data points responsive to the object.

In Example 14, the computer-implemented system of any one of examples 11-13 can optionally where one or more of the plurality of feature values are associated with a three-dimensional (3D) bounding box representing a dimension of the object in a 3D space.

In Example 15, the computer-implemented system of any one of examples 11-14 can optionally where the 3D bounding box representing the dimension of the object in the 3D space may be oriented parallel to a path of the object.

In Example 16, the computer-implemented system of any one of examples 11-15 can optionally where the plurality of feature values include at least one of a distance from the object to the vehicle in the driving scene; an angle of a location of the object with respect to the vehicle; or an angle of a path of the object with respect to the vehicle.

In Example 17, the computer-implemented system of any one of examples 11-16 can optionally where the operations further include executing a sensor test in a simulation that simulates the driving scene; and extracting, from the simulation, the plurality of feature values associated with the driving scene.

In Example 18, the computer-implemented system of any one of examples 11-17 can optionally where the operations further include determining a fidelity of the simulation based on a comparison between a statistical measure of a reference sensor response and the predicted statistical measure of the sensor response.

In Example 19, the computer-implemented system of any one of examples 11-18 can optionally where the road data response prediction model is a generalized linear model (GLM).

Example 20 includes a method including determining a plurality of feature values associated with a driving scene; and querying a road data response prediction model based on the plurality of feature values to obtain a predicted statistical measure of a sensor response for the driving scene with respect to a vehicle in the driving scene, where the predicted statistical measure of the sensor response includes a predicted number of light detection and ranging (LIDAR) data points responsive to the driving scene.

In Example 21, the method of example 20 can optionally include executing a sensor test in a simulation that simulates the driving scene; and determining a fidelity of the simulation based on a comparison between a statistical measure of a reference sensor response and the predicted statistical measure of the sensor response obtained from the querying, where the determining the plurality of feature values is based the simulation.

In Example 22, the method of any one of examples 20-21 can optionally include adjusting a parameter of the simulation based on a comparison between the statistical measure of the reference sensor response and a previous predicted statistical measure of a sensor response, where the executing the sensor test is based on the adjustment.

In Example 23, the method of any one of examples 20-22 can optionally include where the plurality of feature values include at least one of a width of an object in the driving scene; a length of the object; or a height of the object.

In Example 24, the method of any one of examples 20-23 can optionally include where the plurality of feature values include at least one of a distance between an object and the vehicle in the driving scene; an angle of a location of the object with respect to the vehicle; or an angle of a path of the object with respect to the vehicle.

In Example 25, the method of any one of examples 20-24 can optionally include where the road data response prediction model is a generalized linear model (GLM).

Example 26 includes an apparatus comprising means for performing operation of any one of the preceding examples.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

1. A computer-implemented system, comprising:
one or more non-transitory computer-readable media storing instructions, when executed by one or more processing units, cause the one or more processing units to perform operations comprising:
receiving road data collected from a reference driving scene;
extracting, from the road data, features of the reference driving scene;
obtaining, from the road data, response data associated with a vehicle in the reference driving scene and responsive to the extracted features;
calculating a statistical measure of the response data; and
generating a road data response prediction model to map the extracted features of the road data to the statistical measure of the response data.

2. The computer-implemented system of claim 1, wherein:
the response data includes sensing information associated with the reference driving scene; and
the generating the road data response prediction model comprises generating the road data response prediction model to map the extracted features to the statistical measure of the sensing information.

3. The computer-implemented system of claim 1, wherein the statistical measure includes an indication of a quantity of light detection and ranging (LIDAR) data points responsive to an object in the reference driving scene.

4. The computer-implemented system of claim 3, wherein the extracted features include an indication of a dimension of the object.

5. The computer-implemented system of claim 3, wherein the extracted features include an indication of a distance from the object to the vehicle in the reference driving scene.

6. The computer-implemented system of claim 3, wherein the extracted features include an indication of an angle at which the object is located with respect to the vehicle in the reference driving scene.

7. The computer-implemented system of claim 3, wherein the extracted features include an indication of an angle between a path of the object and a path of the vehicle in the reference driving scene.

8. The computer-implemented system of claim 1, wherein the road data response prediction model is a generalized linear model (GLM).

9. A computer-implemented system, comprising:
one or more non-transitory computer-readable media storing instructions, when executed by one or more processing units, cause the one or more processing units to perform operations comprising:
determining a plurality of feature values associated with a driving scene; and
applying a road data response prediction model to the plurality of feature values to obtain a predicted statistical measure of a sensor response for the driving scene with respect to a vehicle in the driving scene.

10. The computer-implemented system of claim 9, wherein the plurality of feature values are associated with an object in the driving scene.

11. The computer-implemented system of claim 10, wherein the predicted statistical measure of the sensor response includes an indication of a predicted number of light detection and ranging (LIDAR) data points responsive to the object.

12. The computer-implemented system of claim 10, wherein one or more of the plurality of feature values are associated with a three-dimensional (3D) bounding box representing a dimension of the object in a 3D space.

13. The computer-implemented system of claim 10, wherein the plurality of feature values include at least one of:
a distance from the object to the vehicle in the driving scene;
an angle of a location of the object with respect to the vehicle; or
an angle of a path of the object with respect to the vehicle.

14. The computer-implemented system of claim 9, wherein the operations further comprise:
executing a sensor test in a simulation that simulates the driving scene; and
extracting, from the simulation, the plurality of feature values associated with the driving scene.

15. The computer-implemented system of claim 14, wherein the operations further comprise:
determining a fidelity of the simulation based on a comparison between a statistical measure of a reference sensor response and the predicted statistical measure of the sensor response.

16. A method comprising:
determining a plurality of feature values associated with a driving scene; and
querying a road data response prediction model based on the plurality of feature values to obtain a predicted statistical measure of a sensor response for the driving scene with respect to a vehicle in the driving scene, wherein the predicted statistical measure of the sensor response includes a predicted number of light detection and ranging (LIDAR) data points responsive to the driving scene.

17. The method of claim 16, further comprising:
executing a sensor test in a simulation that simulates the driving scene; and
determining a fidelity of the simulation based on a comparison between a statistical measure of a reference sensor response and the predicted statistical measure of the sensor response obtained from the querying,
wherein the determining the plurality of feature values is based the simulation.

18. The method of claim 17, further comprising:
adjusting a parameter of the simulation based on a comparison between the statistical measure of the reference sensor response and a previous predicted statistical measure of a sensor response,
wherein the executing the sensor test is based on the adjustment.

19. The method of claim 16, wherein the plurality of feature values include at least one of:
a width of an object in the driving scene;
a length of the object; or
a height of the object.

20. The method of claim 16, wherein the plurality of feature values include at least one of:
a distance between an object and the vehicle in the driving scene;
an angle of a location of the object with respect to the vehicle; or
an angle of a path of the object with respect to the vehicle.
